(19) United States
(12) Patent Application Publication
(10) Pub. No.: US 2010/0044083 A1
(43) Pub. Date: Feb. 25, 2010

(54) Build-up printed circuit board structure for increasing fine circuit density and method of manufacturing the same

(76) Inventor: Chih-Peng Fan, Bade City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/320,798

(22) Filed: Feb. 5, 2009

(30) Foreign Application Priority Data
Aug. 22, 2008 (TW) 97132069

(51) Int. Cl. H05K 1/09; H05K 3/10

(52) U.S. Cl. 174/256; 29/846

(57) ABSTRACT

A method of manufacturing a build-up printed circuit board structure for increasing fine circuit density includes providing a core carrier board; forming a plurality of first conductive pads on a top surface of the core carrier board; forming a first dielectric layer on the core carrier board in order to cover the first conductive pads; drilling the first dielectric layer to form a patterned first electroplated layer on the first dielectric layer; forming a second dielectric layer, and the first dielectric layer and the patterned first electroplated layer being covered by the second dielectric layer; drilling the second dielectric layer and the first dielectric layer to form a patterned second electroplated layer on the second dielectric layer; and forming a third dielectric layer, and the second dielectric layer and the patterned second electroplated layer being covered by the third dielectric layer; and removing the core carrier board.

### BACKGROUND OF THE INVENTION

1. Field of the Invention

The present invention relates to a build-up printed circuit board structure and a method of manufacturing the same, and particularly relates to a build-up printed circuit board structure for increasing fine circuit density and a method of manufacturing the same.

2. Description of Related Art

In the past, various build-up layer methods of high-density IC package substrates and printed circuit boards for achieving finer pitch and multiple layers have been disclosed, including laminations of dielectric films, resin-coated copper (RCC), and pre-preg.

Recently, a more advanced build-up method has been introduced by providing an insulating core layer with completed upper circuit layers and lower circuit layers, in which the upper and lower circuit layers are electrically connected. To establish the connection between the upper and lower circuit layers, a plurality of plated through holes (PTH) are formed in the core layer to connect upper and lower circuit layers. And then utilizing a laminating process to form a dielectric layer onto the core layer, and forming a plurality of vias by laser drilling on the dielectric layer to expose the contact pads of circuit layers. Next, a seed layer is formed over the surface of the dielectric layer, and then utilizing a photolithography process to form patterned photoresistant layer with recesses to expose the vias. Fabricating an electroplating process, a conductive material is formed into the via and the recess of patterned photoresistant layer, and then removing the photoresistant layer and the exposed seed layer under photoresistant layer, a build-up circuit layer is formed and the entire fabrication process is referred to as a semi additive process (SAP).

Referring to FIGS. 1A to 1C, the prior art provides a method for manufacturing a printed circuit board structure, including: providing a core carrier board 110, and two first conductive pads 112 and a first conductive circuit 114 formed on the core carrier board 110; forming a dielectric layer 120 (the dielectric layer 120 is a build-up layer), and the core carrier board 110, the first conductive pads 112 and the first conductive circuit 114 being covered by the dielectric layer 120; drilling the dielectric layer 120 to form a patterned dielectric layer 120a; and then forming two second conductive pads 132, a second conductive circuit 134 and two conductive blind holes 122 on the top side of the patterned dielectric layer 120a by electroplating. The second conductive pads 132 are electrically connected to the first conductive pads 112 via the conductive blind holes 122, respectively. The first conductive circuit 114 and the second conductive circuit 134 are insulated from each other by the patterned dielectric layer 120a. Above-mentioned manufacturing process is SAP (Semi Additive Process).

Referring to FIG. 2 (TW Patent 1253714), the prior art discloses a printed circuit board structure 200, including: two first dielectric layers 202, two second dielectric layers 204 and two third dielectric layers 206. Each first dielectric layer 202 has a plurality of openings and each second dielectric layer 204 has a plurality of openings. The openings are formed as conductive blind holes 208. Each third dielectric layer 206 has a plurality of patterned openings, and each patterned opening has a conductive circuit 210. The conductive circuits 210 are electrically connected to the conductive blind holes 208, respectively. The conductive circuits 210 are insulated from each other by the third dielectric layers 206.

Referring to FIG. 3, another prior art discloses a printed circuit board structure 200′, including: a first dielectric layer 202′, a second dielectric layer 204′ and a third dielectric layer 206′. The first dielectric layer 202′ has a plurality of openings and the second dielectric layer 204′ has a plurality of openings and the third dielectric layer 206′ has a plurality of openings. The openings are formed as conductive blind holes 208′. The conductive circuits 210′ are electrically connected to the conductive blind holes 208′, respectively. The conductive circuits 210′ are insulated from each other by the dielectric layers.

However, when the bump pitches are reduced, the conductive pads need to be also reduced. Therefore, the size of the solder mask opening is reduced. Hence, the fine circuit density of the prior art cannot be further increased.

### SUMMARY OF THE INVENTION

One particular aspect of the present invention is to provide a build-up printed circuit board structure for increasing fine circuit density and a method of manufacturing the same. The present invention can increase bump pitch and fine circuit density.

In order to achieve the above-mentioned aspects, the present invention provides a method of manufacturing a build-up printed circuit board structure for increasing fine circuit density, including: providing a core carrier board; forming a plurality of first conductive pads on a top surface of the core carrier board; forming a first dielectric layer on the core carrier board in order to cover the first conductive pads; drilling the first dielectric layer to form a patterned first electroplated layer on the first dielectric layer; forming a second dielectric layer, and the first dielectric layer and the patterned first electroplated layer being covered by the second dielectric layer; drilling the second dielectric layer and the first dielectric layer to form a patterned second electroplated layer on the second dielectric layer; forming a third dielectric layer, and the second dielectric layer and the patterned second electroplated layer being covered by the third dielectric layer; and removing the core carrier board.

In order to achieve the above-mentioned aspects, the present invention provides a build-up printed circuit board structure for increasing fine circuit density, including: a first dielectric layer, a second dielectric layer and a third dielectric layer and a plurality of two-step conductive blind holes. The first dielectric layer has a plurality of first conductive pads embedded themselves in its bottom side and a plurality of first conductive circuits formed on its top side. The second dielectric layer is formed on the top side of the first dielectric layer, and the second dielectric layer has a plurality of second conductive circuits formed on its top side. The third dielectric layer is formed on the top side of the second dielectric layer, and the third dielectric layer has a plurality of second conductive pads formed on its top side. The two-step conductive blind holes are formed between the first dielectric layer and the second dielectric layer or formed between the second dielectric layer and the third dielectric layer, wherein and the two-step conductive blind holes are electrically connected to the corresponding first conductive pads and the corresponding second conductive pads.

Hence, the present invention has the following advantages:

1. The first dielectric layer, the second dielectric layer and the third dielectric layer are formed by a build-up process in order to form a plurality of two-step conductive blind holes, so that the bump pitches between the first conductive pads is reduced. Therefore, the number of the first conductive circuits and the second conductive circuits are increased in order to obtain a PCB with fine circuit density and multi-pin.

2. The present invention can achieve the object of re-distribution, so that the sizes of the first conductive pads and the second conductive pads are increased. Therefore, the size of the solder mask opening is increased.

3. The gaps between the two-step conductive blind holes and the conductive pads are larger than the one-step conductive blind holes and the conductive pads. Hence, using two-step conductive blind holes can release space for circuit and the present invention has a large wiring space.

It is to be understood that both the foregoing general description and the following detailed description are exemplary, and are intended to provide further explanation of the invention as claimed. Other advantages and features of the invention will be apparent from the following description, drawings and claims.

### BRIEF DESCRIPTION OF THE DRAWINGS

The various objectives and advantages of the present invention will be more readily understood from the following detailed description when read in conjunction with the appended drawings, in which:

FIGS. 1A to 1C are cross-sectional, schematic views of a printed circuit board structure of the prior art, at different stages of the manufacturing processes, respectively;

FIG. 2 is a cross-sectional, schematic view of a build-up printed circuit board structure of the prior art;

FIG. 3 is a cross-sectional, schematic view of another build-up printed circuit board structure of the prior art;

FIGS. 4A to 4J are cross-sectional, schematic views of a build-up printed circuit board structure for increasing fine circuit density of the present invention, at different stages of the manufacturing processes, respectively; and

FIGS. 5A to 5C are top, schematic views of a build-up printed circuit board structure for increasing fine circuit density of the present invention, at different stages of the manufacturing processes, respectively.

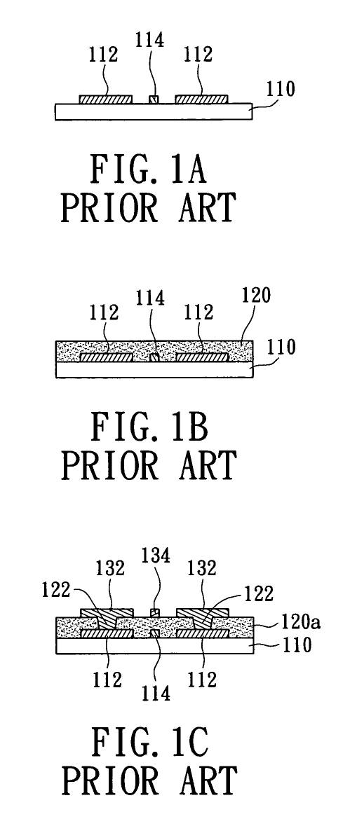

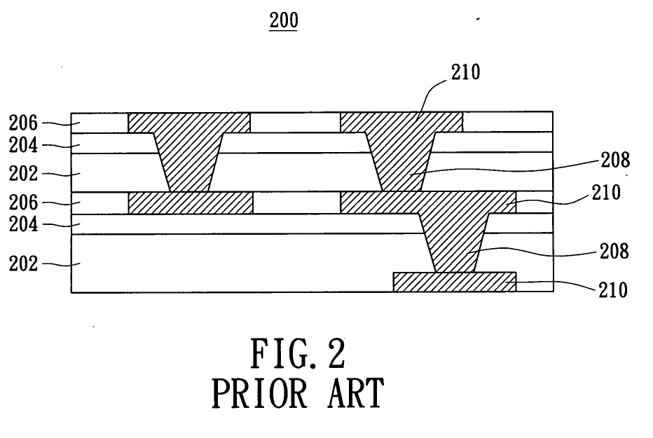

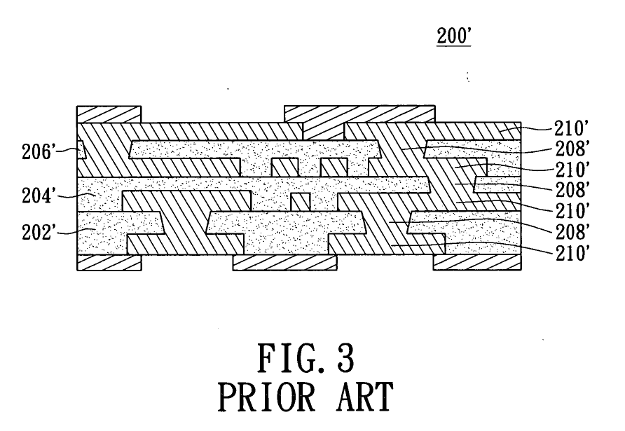

### DETAILED DESCRIPTION OF PREFERRED EMBODIMENTS

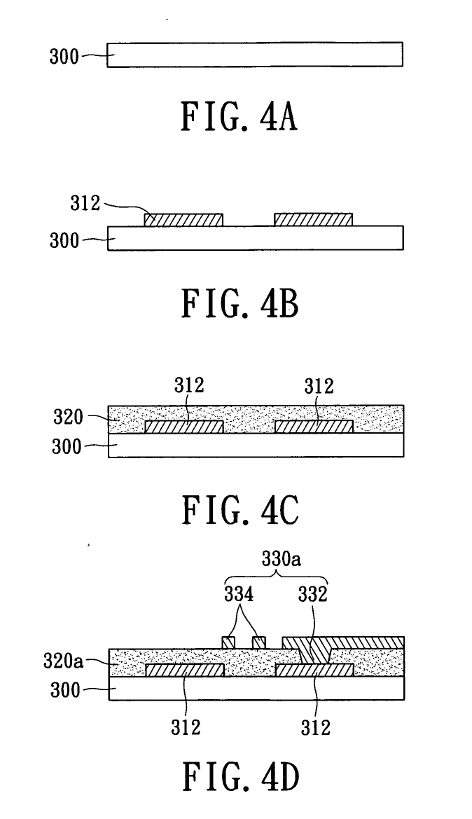

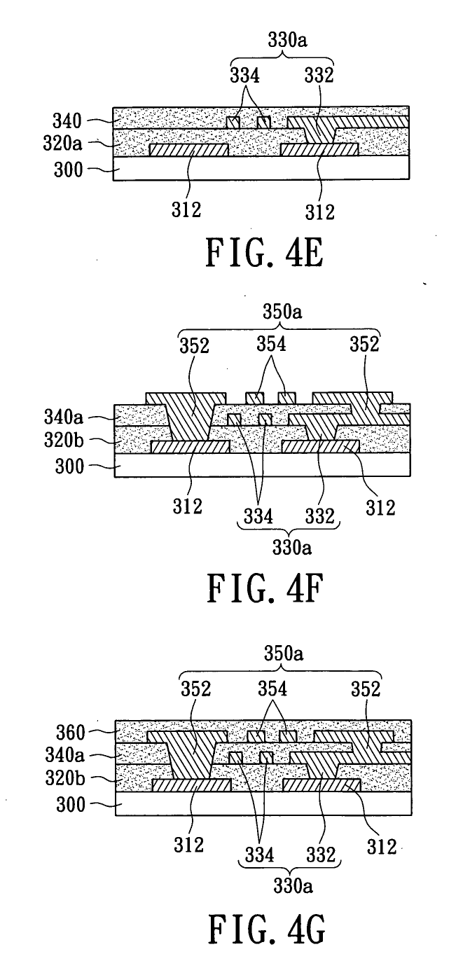

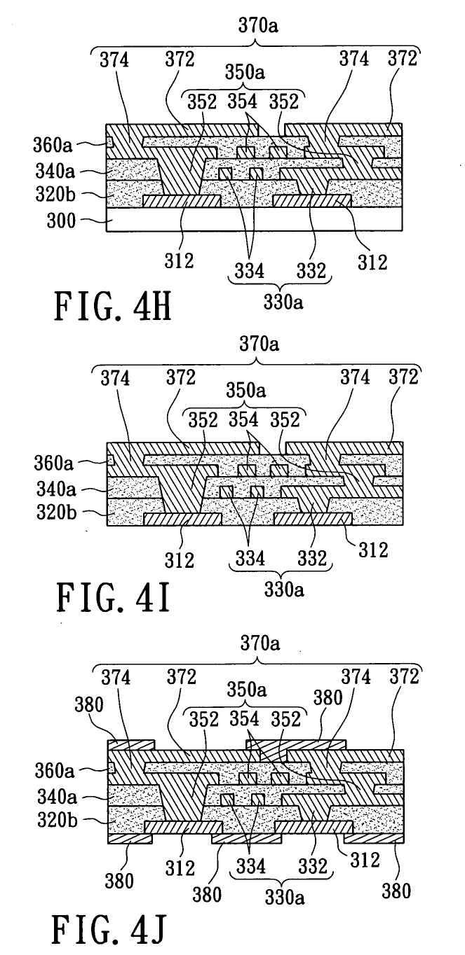

Referring to FIG. 4A, the present invention provides a core carrier board 300 that can be an organic insulating substrate or a metal substrate. In the present embodiment, the core carrier board 300 is a metal substrate.

Referring to FIG. 4B, a plurality of first conductive pads 312 are formed on a top surface of the core carrier board 300 by an electroless copper process, a lithography process, an electroplating process and a wet etching process in sequence. The first conductive pads 312 are selected from the group consisting of Au, Ni, Pd, Ag, Sn, Ni/Pd, Cr/Ti, Ni/Au, Cu/Ni/Au, Pd/Au, Ni/Pd/Au, Cu, Cr, Ti, Cu/Cr and Sn/Pb. In the present invention, the first conductive pads 312 are copper.

Referring to FIG. 4C, a first dielectric layer 320 is formed on the core carrier board 300 in order to cover the first conductive pads 312. The first dielectric layer 320 can be a photosensitive organic resin (such as ABF (Ajinomoto Build-up Film) or PP (Pre-Preg) or BT (Bismaleimide Triazine Resin)), a non-photosensitive resin, or a mixture of epoxy and glass fiber. In the present invention, the first dielectric layer 320 is ABF (Ajinomoto Build-up Film).

Referring to FIG. 4D, the first dielectric layer 320 is laser-drilled and plated to form a patterned first dielectric layer 320a with a first conductive blind hole 332. A patterned first electroplated layer 330a is formed on the patterned first dielectric layer 320a in order to form a plurality of first conductive circuits 334. One part of the patterned first electroplated layer 330a is filled into the first conductive blind hole 332 in order to electrically connect to one part of the first conductive pads 312. In the present invention, the patterned first electroplated layer 330a is formed by a lithography process and an electroplating process. The electroplating process further includes an electroless copper process and a PTH (Plating Through Hole) process. The patterned first electroplated layer 330a is copper.

Referring to FIG. 4E, the first dielectric layer 320 and the patterned first electroplated layer 330a are covered by a second dielectric layer 340.

Referring to FIG. 4F, the second dielectric layer 340 is laser-drilled and plated to form a patterned second dielectric layer 340a with a second conductive blind hole 352. A patterned second electroplated layer 350a is formed on the patterned second dielectric layer 340a in order to form a plurality of second conductive circuits 354. One part of the patterned second electroplated layer 350a is filled into the second conductive blind hole 352 in order to electrically connect to one part of the first conductive circuits 334 and one part of the first conductive pads 312 via the first conductive blind hole 332. Moreover, the patterned first dielectric layer 320a is laser-drilled and plated to form another patterned first dielectric layer 320b. The second dielectric layer 340 and the patterned first dielectric layer 320a are laser-drilled and plated together to form another second conductive blind hole 352. One part of the patterned second electroplated layer 350a is filled into above-mentioned another second conductive blind hole 352 in order to electrically connect to one part of the first conductive pads 312. In the present invention, the patterned second electroplated layer 350a is formed by a lithography process and an electroplating process. The electroplating process further includes an electroless copper process and a PTH (Plating Through Hole) process. The patterned second electroplated layer 350a is copper.

Referring to FIG. 4G, the patterned second dielectric layer 340a and the patterned second electroplated layer 350a are covered by a third dielectric layer 360.

Referring to FIG. 4H, the third dielectric layer 360 is laser-drilled and plated to form a patterned third dielectric layer 360a with a plurality of third conductive blind holes 374. A patterned third electroplated layer 370a is formed on the patterned third dielectric layer 360a in order to form a plurality of second conductive pads 372. One part of the patterned third electroplated layer 370a is filled into the third conductive blind holes 374 in order to electrically connect to the second conductive pads 372 and second conductive blind hole 352.

In the present invention, the patterned third dielectric layer 360a is formed by a lithography process and an electroplating process. The electroplating process further includes an electroless copper process and a PTH (Plating Through Hole) process. The patterned third dielectric layer 360a is copper.

Referring to FIG. 4I, the core carrier board 300 is removed by wet etching or brushing and then formed a plurality of first conductive pads 312 embedded themselves in bottom side of the pattern first dielectric layer 320.

Referring to FIG. 4J, a plurality of solder masks 380 are formed on one part of the top side of the second conductive pads 372, on one part of the top side of the patterned third dielectric layer 360a, on one part of the bottom side of the first conductive pads 312, and on the bottom side of the patterned first dielectric layer 320b in order to finish a build-up printed circuit board for increase circuit density. In addition, the solder masks 380 are formed by printing, roller coating, spraying, curtain coating or spin coating. In the present invention, the solder masks 380 are formed by printing, and the solder masks 380 are made of green paint. Moreover, each solder mask opening 381 is formed between two solder masks 380.

Furthermore, the patterned first electroplated layer 330a has a plurality of first conductive blind holes 332, and the patterned second electroplated layer 350a has a plurality of second conductive blind hole 352. The first conductive circuits 334 and the second conductive circuits 354 are insulated from each other by the patterned second dielectric layer 340a.

Moreover, the first conductive blind holes 332 passes through the first dielectric layer 320. The second conductive blind hole 352 passes through the second dielectric layer 340. The third conductive blind hole 374 passes through the third dielectric layer 360. One part of the second conductive blind hole 352 is a two-step conductive blind hole. The other second conductive blind hole 352, the first conductive blind holes 332 and the third conductive blind hole 374 are single-step conductive blind holes. The two-step conductive blind hole is electrically connected to the first conductive pad 312, the third conductive hole 374 and the second conductive pad 372. The first dielectric layer 320, the second dielectric layer 340 and the third dielectric layer 360 are formed by a build-up process.

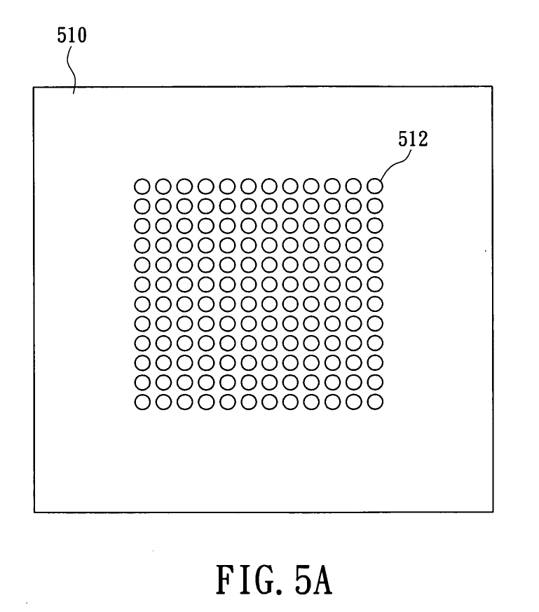

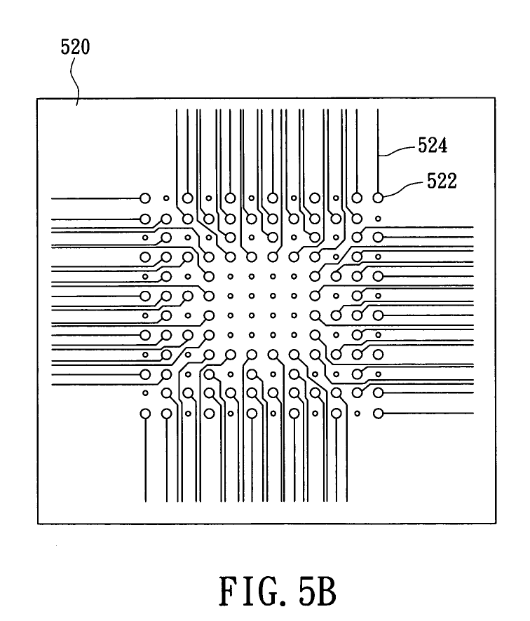

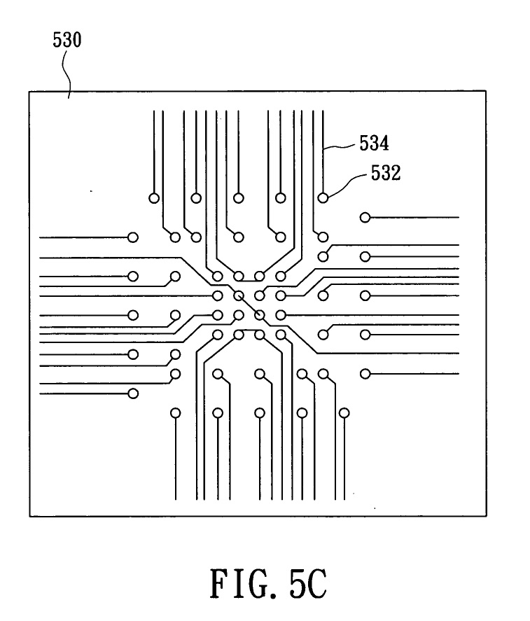

Referring to FIGS. 5A to 5C, the present invention provides a build-up printed circuit board structure for increasing the density of fine circuit, including: a first build-up layer 510, a second build-up layer 520 and a third build-up layer 530.

The first build-up layer 510 has a plurality of conductive pads 512.

The second build-up layer 520 has a plurality of conductive blind holes 522 and a plurality of conductive circuits 524. The conductive blind holes 522 are electrically connected to the conductive circuits 524 and the conductive pads 512 of the first build-up layer 510, respectively.

The third build-up layer 530 has a plurality of conductive blind holes 532 and a plurality of conductive circuits 534. The conductive blind holes 532 are electrically connected to the conductive circuits 534 and the conductive blind holes 522 of the second build-up layer 520, respectively.

The first build-up layer 510, the second build-up layer 520 and the third build-up layer 530 are arranged as one type of six rows fan out in order to obtain the object of re-distribution. Moreover, the size of the conductive pads 512 is increased by using the two-step conductive blind holes (522, 532), so that the size of the solder mask opening 381 (as shown in FIG. 4J) is increased.

Although the present invention has been described with reference to the preferred best molds thereof, it will be understood that the present invention is not limited to the details thereof. Various substitutions and modifications have been suggested in the foregoing description, and others will occur to those of ordinary skill in the art. Therefore, all such substitutions and modifications are intended to be embraced within the scope of the present invention as defined in the appended claims.

What is claimed is:

1. A method of manufacturing a build-up printed circuit board structure for increasing fine circuit density, comprising:
providing a core carrier board;
forming a plurality of first conductive pads on a top surface of the core carrier board;
forming a first dielectric layer on the core carrier board in order to cover the first conductive pads;
drilling the first dielectric layer to form a patterned first electroplated layer on the first dielectric layer;
forming a second dielectric layer, wherein the first dielectric layer and the patterned first electroplated layer are covered by the second dielectric layer;
drilling the second dielectric layer and the first dielectric layer to form a patterned second electroplated layer on the second dielectric layer;
forming a third dielectric layer, wherein the second dielectric layer and the patterned second electroplated layer are covered by the third dielectric layer; and
removing the core carrier board.

2. The method as claimed in claim 1, wherein the first conductive pads are formed by an electroless process, a lithography process, an electroplating process and a wet etching process in sequence.

3. The method as claimed in claim 1, wherein after the step of forming the patterned first electroplated layer, the method further comprises: forming at least one first conductive blind hole by electroplating, wherein the first conductive blind hole is electrically connect to one part of the first conductive pads.

4. The method as claimed in claim 3, wherein one part of the patterned first electroplated layer is filled into the first conductive blind hole.

5. The method as claimed in claim 1, wherein after the step of forming the patterned second electroplated layer, the method further comprises: forming at least one second conductive blind hole by electroplating, wherein the second conductive blind hole is electrically connect to at least one of the first conductive pads.

6. The method as claimed in claim 5, wherein one part of the patterned second electroplated layer is filled into the second conductive blind hole.

7. The method as claimed in claim 1, wherein the first dielectric layer, the second dielectric layer and the third dielectric layer are formed by a build-up process.

8. The method as claimed in claim 7, wherein the first dielectric layer, the second dielectric layer and the third dielectric layer are photosensitive organic resin, a non-photosensitive resin or a mixture of epoxy and glass fiber, and the photosensitive organic resin is ABF (Ajinomoto Build-up Film) or PP (Pre-Preg) or BT(Bismaleimide Triazine Resin).

9. The method as claimed in claim 1, wherein the core carrier board is removed by wet etching or brushing.

10. The method as claimed in claim 1, wherein after the step of forming a third dielectric layer, the method further comprises:
drilling the third dielectric layer to form a patterned third dielectric layer, wherein a patterned third electroplated layer is formed on the patterned third dielectric layer in order to form a plurality of second conductive pads; and
forming a plurality of solder masks on one part of the top side of the second conductive pads and on one part of the bottom side of the first conductive pads and on the bottom side of the first dielectric layer.

11. The method as claimed in claim 10, wherein the patterned first electroplated layer, the patterned second electroplated layer and the patterned third electroplated layer are formed by a lithography process and an electroplating process in sequence.

12. The method as claimed in claim 11, wherein the electroplating process includes an electroless process and a plating through hole process.

13. The method as claimed in claim 10, wherein one part of the patterned third electroplated layer is filled into the third conductive blind holes in order to electrically connect to the second conductive pads and second conductive blind hole.

14. The method as claimed in claim 10, wherein the solder masks are formed by printing, roller coating, spraying, curtain coating or spin coating.

15. A build-up printed circuit board structure for increasing fine circuit density, comprising:
a first dielectric layer having a plurality of first conductive pads embedded themselves in its bottom side and a plurality of first conductive circuits formed on its top side;
a second dielectric layer formed on the top side of the first dielectric layer, wherein the second dielectric layer has a plurality of second conductive circuits formed on its top side; and
a third dielectric layer formed on the top side of the second dielectric layer, wherein the third dielectric layer has a plurality of second conductive pads formed on its top side; and
a plurality of two-step conductive blind holes formed between the first dielectric layer and the second dielectric layer or formed between the second dielectric layer and the third dielectric layer, wherein and the two-step conductive blind holes are electrically connected to the corresponding first conductive pads and the corresponding second conductive pads.

16. The build-up printed circuit board structure as claimed in claim 15, wherein the first conductive pads and the second conductive pads are selected from the group consisting of Au, Ni, Pd, Ag, Sn, Ni/Pd, Cr/Ti, Ni/Au, Cu/Ni/Au, Pd/Au, Ni/Pd/Au, Cu, Cr, Ti, Cu/Cr and Sn/Pb.

17. The build-up printed circuit board structure as claimed in claim 15, wherein the first dielectric layer, the second dielectric layer and the third dielectric layer are photosensitive organic resin, a non-photosensitive resin or a mixture of epoxy and glass fiber, and the photosensitive organic resin is ABF (Ajinomoto Build-up Film) or PP (Pre-Preg) or BT(Bismaleimide Triazine Resin).

18. The build-up printed circuit board structure as claimed in claim 15, wherein the first conductive circuits, the second conductive circuits and the two-step conductive blind holes are selected from the group consisting of Au, Ni, Cu, Ag, Sn, Pb, Bi, Pd, Al, Fe, Cd and Zn.

19. The build-up printed circuit board structure as claimed in claim 15, further comprising: a plurality of solder masks, wherein one part of the solder masks are formed on the bottom side of the first dielectric layer and on the bottom side of one part of the first conductive pads, and other solder masks are formed on the top side of one part of the third dielectric layer and on the top side of one part of the second conductive pads.

20. The build-up printed circuit board structure as claimed in claim 19, wherein the solder masks are made of green paint.
